(19) United States
(12) Patent Application Publication
(10) Pub. No.: US 2026/0321554 A1
(43) Pub. Date: Oct. 15, 2026

(54) Semiconductor Processing System with Multiple Plasma Sources and Horizontal Scan

(71) Applicant: Applied Materials, Inc., Santa Clara, CA (US)

(72) Inventor: Kevin M. Daniels, Lynnfield, MA (US)

(21) Appl. No.: 19/179,852

(22) Filed: Apr. 15, 2025

(51) Int. Cl. H01J 37/32; H10P 72/76

(52) U.S. Cl. CPC H01J 37/32715; H01J 37/32733; H01J 37/32899; H01J 2237/184; H01J 2237/202; H10P 72/7618

(57) ABSTRACT

A cluster tool that has one or more processing chambers that are each coupled to two or more plasma sources is disclosed. The two or more plasma sources each direct a respective output beam toward a horizontally moving workpiece. The platen is disposed on a movable platen assembly within a processing chamber. The movable platen assembly moves horizontally to allow the output beams from two different plasma sources to process a workpiece disposed on the platen. The processing chambers also include a vacuum robot to remove workpieces from a load lock and place them on the movable platen assembly and to remove processed workpiece from the movable platen assembly and return them to the load lock. In some cluster tools, there may be two load locks per processing chamber to improve throughput. Additionally, a buffer station may be located between the load lock and the processing chamber.

### FIELD

Embodiments of the present disclosure relate to a semiconductor processing system that includes a horizontal scan mechanism, and more particularly a processing system that allows a workpiece to pass through output beams from two plasma sources using a horizontal scan mechanism.

### BACKGROUND

Semiconductor workpieces, such as silicon wafers, silicon oxide wafers, gallium nitride wafers and others, may be implanted with impurities to create semiconductor devices, such as transistors. In operation, an ion source may be used to generate an ion beam. In other embodiments, a beam of radicals may be created. In some embodiments, a cluster tool may be used, where workpieces enter the cluster tool and are distributed among a plurality of process chambers for processing. The cluster tool may include an atmospheric robot that accepts workpieces from one or more FOUPs (Front Opening Universal Pods) and places them in a load lock. The cluster tool also includes a central distribution robot, located within a central distribution hub within the vacuum chamber, which removes the workpiece from the load lock and distributes it to one of the process chambers.

In some embodiments, the process chamber may include a platen that is rotatable between a horizontal orientation, which allows workpieces to be loaded onto the platen and a vertical orientation, which allows the workpiece to be processed. Further, the platen may be disposed on the end of a movable shaft, which allows relative movement between the platen and the incoming ion beam in the vertical direction. In some systems, the shaft extends outside the process chamber, such as through use of an air bearing. Further, because of the height used for the vertical scan, the platen may be located at a different elevation than the central distribution robot. Thus, in some systems, each process chamber also includes a dedicated robot that is used to transfer the workpiece from the location where it is placed by the central distribution robot, to the platen. Furthermore, in some systems, the location where the central distribution robot places the workpiece within the process chamber may be an orienter, which is used to establish a known orientation of the workpiece.

Thus, in this configuration, the cluster tool includes one atmospheric robot, one central distribution robot, N process chambers, wherein N may typically be between 1 and 6, each process chamber having an orienter, a dedicated robot, a movable shaft with an air bearing and a rotatable platen.

Consequently, it would be beneficial if there was a cluster tool and a process chamber with a reduced number of complex components. Such a cluster tool may be less expensive and also occupy less space.

### SUMMARY

A cluster tool that has one or more processing chambers that are each coupled to two or more plasma sources is disclosed. The two or more plasma sources each direct a respective output beam toward a horizontally moving workpiece. The platen is disposed on a movable platen assembly within each processing chamber. The movable platen assembly moves horizontally to allow the output beams from two different plasma sources to process a workpiece disposed on the platen. The processing chambers may also include a vacuum robot to remove workpieces from a load lock and place them on the movable platen assembly and to remove processed workpiece from the movable platen assembly and return them to the load lock. In some cluster tools, there may be two load locks per processing chamber to improve throughput. Additionally, a buffer station may be located between the load lock and the processing chamber. The cluster tool also includes a front-end system that moves workpieces from an atmospheric environment to the load lock.

According to one embodiment, a cluster tool is disclosed. The cluster tool comprises a front-end system, including an atmospheric robot; a processing chamber configured to be pumped to near vacuum conditions, the processing chamber including a vacuum robot disposed within the processing chamber; a first plasma source and a second plasma source coupled to the processing chamber; a load lock disposed between the front-end system and the processing chamber; and a movable platen assembly disposed in the processing chamber, wherein the movable platen assembly moves horizontally such that a workpiece supported by a platen in the movable platen assembly is configured to be treated by a first output beam from the first plasma source and a second output beam from the second plasma source. In some embodiments, a second load lock is disposed between the front-end system and the processing chamber. In some embodiments, the first plasma source and the second plasma source are identical. In some embodiments, the first plasma source and the second plasma source are configured with one or more parameters that are different such that two processes are performed on each workpiece. In certain embodiments, the one or more parameters comprises one or more of extraction voltage, duty cycle, RF power, gas species, gas flow rate, gas ratio or gas pressure. In some embodiments, one or more parameters of the movable platen assembly are changed as the platen passes through the first output beam and the second output beam. In certain embodiments, the one or more parameters comprises one or more of scan speed, bias voltage or duty cycle. In some embodiments, the movable platen assembly moves in a reciprocating manner from a starting position near the vacuum robot to an ending position, past the second plasma source, and then returns to the starting position. In certain embodiments, unprocessed workpieces are placed on the movable platen assembly and processed workpieces are removed from the movable platen assembly while the movable platen assembly is in the starting position. In some embodiments, the cluster tool comprises a second processing chamber, two additional plasma sources coupled to the second processing chamber, and a second vacuum robot, dedicated to the second processing chamber.

According to another embodiment, a cluster tool is disclosed. The cluster tool comprises a front-end system, including an atmospheric robot; a processing chamber configured to be pumped to near vacuum conditions; a first plasma source and a second plasma source coupled to the processing chamber; a movable platen assembly disposed in the processing chamber, wherein the movable platen assembly moves horizontally such that a workpiece supported by a platen in the movable platen assembly is configured to be treated by a first output beam from the first plasma source and a second output beam from the second plasma source; a buffer station maintained at near vacuum conditions, in communication with the processing chamber, the buffer station including a vacuum robot disposed within the buffer station; and a load lock disposed between the front-end system and the buffer station. In some embodiments, an orienter is disposed in the buffer station. In some embodiments, a cassette is disposed in the buffer station. In some embodiments, the cluster tool comprises a second processing chamber, two additional plasma sources coupled to the second processing chamber, and a second vacuum robot disposed in the buffer station. In certain embodiments, a cassette is disposed in the buffer station at a location such that the vacuum robot and the second vacuum robot both have access to it. In some embodiments, a second load lock is disposed between the front-end system and the buffer station. In some embodiments, the first plasma source and the second plasma source are identical. In some embodiments, the first plasma source and the second plasma source are configured with one or more parameters that are different such that two processes are performed on each workpiece. In certain embodiments, the one or more parameters comprises one or more of extraction voltage, duty cycle, RF power, gas species, gas flow rate, gas ratio, or gas pressure. In some embodiments, one or more parameters of the movable platen assembly are changed as the platen passes through the first output beam and the second output beam.

### BRIEF DESCRIPTION OF THE FIGURES

For a better understanding of the present disclosure, reference is made to the accompanying drawings, which are incorporated herein by reference and in which:

FIG. 1 shows a top view of the cluster tool according to one embodiment with the movable platen assembly in the starting position;

FIG. 2 shows a top view of the cluster tool according to one embodiment with the movable platen assembly in the ending position;

FIG. 3 shows a side view of the embodiment of FIG. 1;

FIG. 4 shows a top view of the cluster tool according to a second embodiment with the movable platen assembly in the starting position; and

FIG. 5 shows a side view of the embodiment of FIG. 4.

### DETAILED DESCRIPTION

As described above, cluster tools that are used for semiconductor processing may have many components. It would be desirable to create a new cluster tool that utilized fewer components and occupied less space.

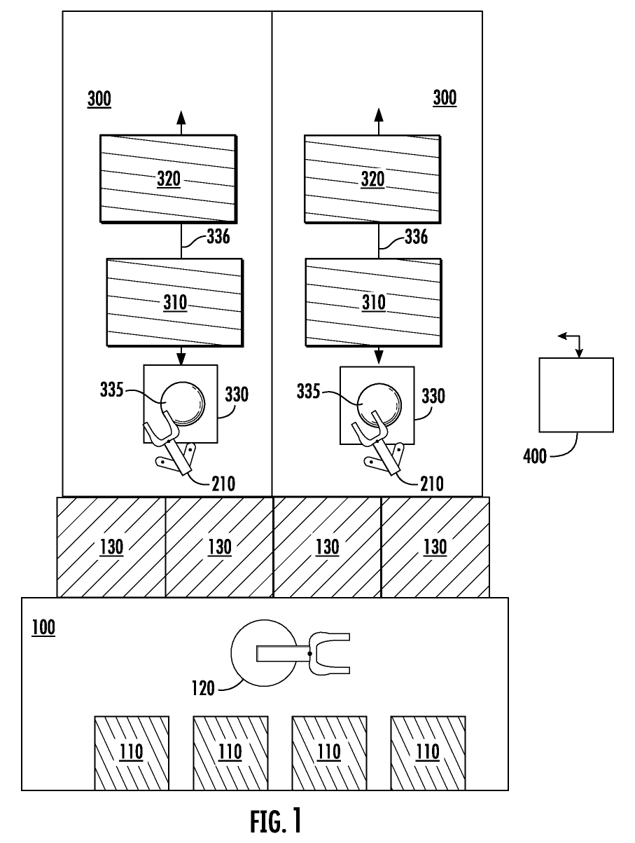

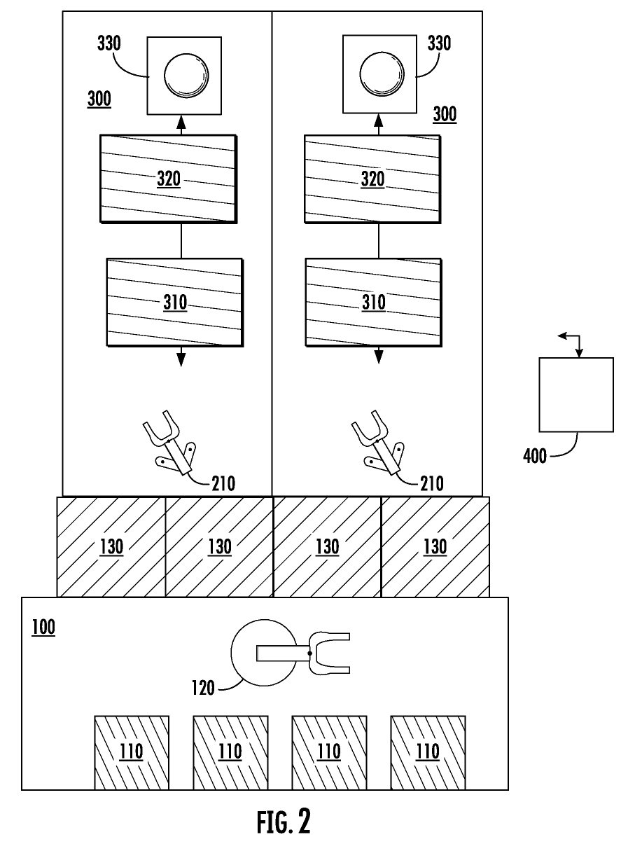

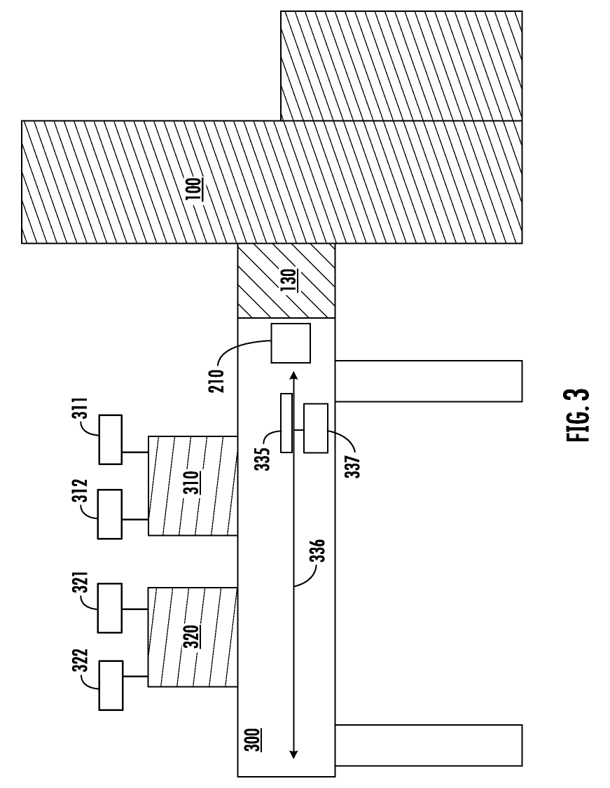

FIGS. 1-3 show a first embodiment of a cluster tool that achieves these objectives. FIG. 1 shows a top view wherein the movable platen assembly is in the starting position; FIG. 2 shows a top view wherein the movable platen assembly is in the ending position; and FIG. 3 is a side view of the embodiment of FIG. 1. The cluster tool includes a front-end system 100, in communication with one or more processing chambers 300.

The front-end system 100 includes one or more receptacles 110 that each accept a front opening universal pod (FOUP). An atmospheric robot 120 is located within the front-end system 100 and is configured to move workpieces from one of the FOUPs to a load lock 130 and to return processed workpieces from the load lock 130 to the FOUP. The load lock 130 enables communication between the front-end system 100, which is at atmospheric conditions, and the processing chambers 300, which are each maintained at near vacuum conditions using a vacuum pump. In this disclosure, “near vacuum conditions” denotes an environment with a pressure of less than 50 milliTorr. The load lock 130 has two doors; a first door in communication with the atmospheric robot 120, and a second door in communication with the processing chamber 300. In operation, only one door is opened at a time. The atmospheric robot 120 places a workpiece in the load lock 130. The first door is then closed and the interior of the load lock 130 is pumped down to near vacuum pressure. The second door is then opened and the workpiece is removed by the vacuum robot 210. Processed workpieces are moved in the opposite direction. First, the processed workpiece is placed in the load lock 130 through the open second door. The second door is then closed and the interior of the load lock 130 is vented to atmospheric conditions. The first door is then opened and the processed workpiece is removed by the atmospheric robot 120.

In some embodiments, there may be a plurality of load locks 130. For example, there may be two load locks for each processing chamber 300. Further, in some embodiments, each load lock 130 may have one or more slots, wherein each slot is capable of holding one workpiece. Note that the front-end system 100 may be used to supply workpieces to one or more processing chambers 300.

An orienter may also be disposed in the cluster tool. The orienter is used to align the workpiece to a known orientation. For example, each workpiece typically has a notch or other indicia. The orienter is used to rotate the workpiece such that the notch is located at a specific position.

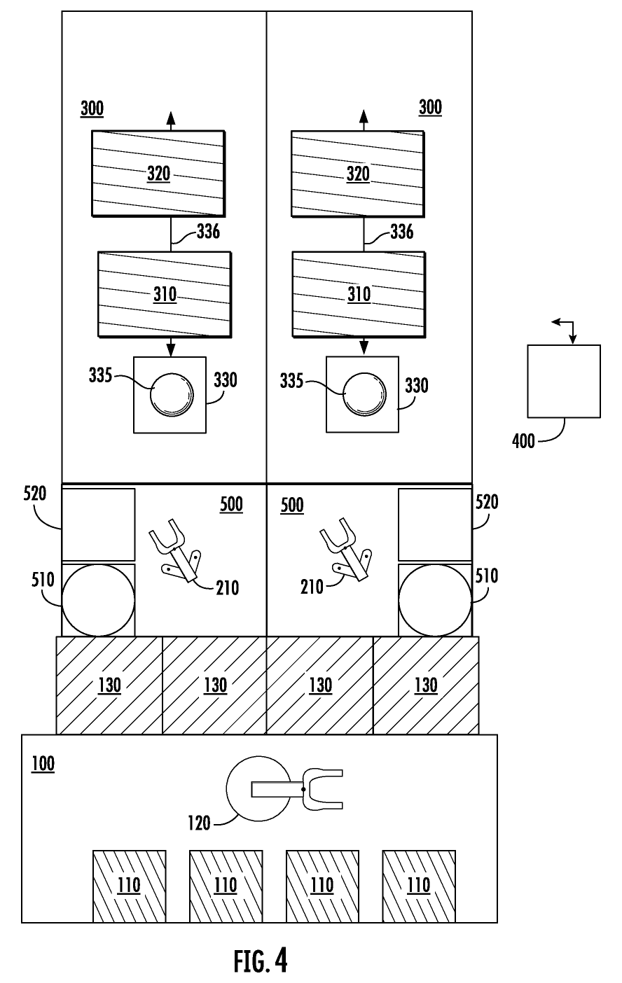

In certain embodiments, the orienter may be disposed in near vacuum conditions, as described in more detail below with respect to FIG. 4. In certain embodiments, the orienter is disposed outside the cluster tool such that workpieces disposed in the FOUPS are already aligned. In some embodiments, the orienter is located within the load lock 130. For example, the load lock 130 may have two slots, wherein the first slot also includes an orienter. In this way, workpieces that enter the cluster tool are placed in the first slot, where they are oriented, while processed workpieces are placed in the second slot.

Further, there may be multiple orienters. For example, if there are multiple load locks 130, there may be one orienter in each load lock. If the orienter is separate from the load lock, the number of orienters may be the same or different from the number of load locks 130.

Each processing chamber 300 may include a vacuum robot 210. One or more processing chambers 300 are disposed adjacent to a respective vacuum robot 210. The vacuum robots 210 may have one or more arms that allow the vacuum robots 210 to be able to access the load locks 130, as well as the movable platen assembly 330 in the corresponding processing chamber 300. In some embodiments, the vacuum robots 210 may be SCARA (Selective Compliance Articulated Robotic Arm) type robots, capable of movement in the height direction, the radial direction and rotation in the yaw direction.

In some embodiments, the vacuum robots 210 may have two arms. In some embodiments, the arms may be able to move independently. In other embodiments, the arms may be linked in one or more directions, such as the rotational direction.

Finally, as noted above, the cluster tool includes one or more processing chambers 300, each at near vacuum conditions. While FIG. 1 shows two processing chambers 300, the disclosure is not limited to the embodiment shown in FIG. 1. There may be more or fewer processing chambers 300, each in communication with a respective vacuum robot 210. In some embodiments, one or more load locks 130 are dedicated to each processing chamber 300. In FIG. 1-2, there are two load locks 130 dedicated to each processing chamber 300. In certain embodiments, the processing chambers 300 may be used to perform pattern shaping, which is the precise and unidirectional modification of the dimensions of on-workpiece features to enhanced the performance of extreme ultraviolet (EUV) patterning.

Two or more plasma sources are coupled to each processing chamber. FIGS. 1-3 show a first plasma source 310 and a second plasma source 320. These plasma sources may be inductively coupled plasma chambers, wherein an antenna is disposed inside or outside the plasma chamber and supplied with RF power. Gasses, which may be deposition species, etching species or cleaning species, may be introduced into the plasma chamber. The plasma sources may be used to perform etching, deposition, or another type of process. An output beam exits each plasma source. In some embodiments, the output beam may comprise radicals. In this scenario, the gas pressure within the plasma source may be maintained at a higher level than the pressure outside the plasma source to push the radicals out of the plasma source. In other embodiments, the output beam may comprise ions. In yet other embodiments, the output beam may comprise ions and radicals. In the case where the output beam contains ions, the walls of the plasma chamber may be electrically conductive such that an extraction voltage may be applied to the walls of the plasma chamber or to the platen (described below). The extraction voltage may be varied using an extraction power supply, and may be pulsed at a duty cycle to extract ions in some embodiments. Note that while the disclosure describes each plasma source as having an output beam, it is understood that the plasma sources may also include two or more output beams.

Each processing chamber 300 also includes a movable platen assembly 330. The first plasma source 310 and the second plasma source 320 each have an extraction aperture that is much wider in one direction, referred to as the width direction, than the second direction, referred to as the height direction. The width direction of the two extraction apertures are parallel to one another and perpendicular to the direction of travel 336 of the movable platen assembly 330. Further, the first plasma source 310 and the second plasma source 320 are oriented such that the workpiece is processed while in the horizontal orientation. In this way, the platen 335 does not have to rotate between a loading position and a processing position. Further, unlike traditional platens, the platen 335 is moved along the horizontal direction, while the output beams are directed toward the platen 335 so that the output beams may treat the workpiece. While FIG. 3 shows the output beams being directed downward, it is understood that the output beams may be directed upward toward the platen 335 in some embodiments. In some embodiments, the platen 335 may be able to rotate about an axis that is parallel to the surface of the workpiece and parallel to the width direction. In certain embodiments, the platen 335 may also be able to rotate about an axis that is parallel to the surface of the workpiece and perpendicular to the width direction.

Note that in some embodiments, the first plasma source 310 and the second plasma source 320 are the same type of plasma source, utilizing the same parameters and same species, such that the workpiece is processed four times as the movable platen assembly 330 moves from the starting position (shown in FIG. 1) to the ending position (shown in FIG. 2) and back to the starting position. In other embodiments, the plasma sources may be configured differently. For example, both plasma sources may be configured to perform an etching or deposition process; however, one or more parameters associated with each plasma source may differ. These one or more parameters include the RF power supplied to each antenna by the respective RF power supply 311, 321, the magnitude and/or duty cycle of the extraction voltage supplied by the respective extraction voltage power supply 312, 322, the gas pressure within the chamber or the flow rate of the gas that is introduced into the chamber. In one specific embodiment, the same gas species may be used for both plasma sources, however, there may be different gas flow rates, gas ratios (when multiple gas species are used), or gas pressures. This may, for example, allow one plasma source to perform a process which is primarily polymer deposition, while the other plasma source performs a process which is primarily directional etching. This may divide the shrink and push parts of the application between the two plasma sources.

In some embodiments, the temperature of each plasma source may also be independently controlled. Alternatively, both plasma sources may be configured to perform a cleaning process. In this scenario, the plasma sources may be configured identically or one or more parameters may differ.

The movable platen assembly 330 includes a platen 335 and a scanning system. The platen 335 may include lift pins. In certain embodiments, the platen 335 is capable of multiple degrees of freedom. For example, the platen 335 may be capable of rotating about an axis that is perpendicular to the top surface of the platen 335 (referred to as the twist axis). The platen may also be capable of rotation about an axis that is perpendicular to the twist axis and perpendicular to the direction of travel 336 (referred to as z-axis tilt). The platen 335 may be an electrostatic platen, wherein electrostatic forces are used to clamp the workpiece to the platen 335. The platen 335 may also have the ability to control or vary its temperature. Additionally, in some embodiments, the platen 335 may be biased using a workpiece bias power supply 337. This workpiece bias power supply 337 may be configured to have a range of bias voltages and a range of duty cycles. Note that the configuration of the workpiece bias power supply 337 may change as the workpiece passes through the output beams from the two different plasma sources.

The scanning system may be any suitable system that achieves reciprocating horizontal motion. For example, the scanning system may be a magnetic levitation system. In other embodiments, the scanning system may comprise a horizontal air bearing with a shaft affixed to the platen 335, which is linearly translated to move the platen 335 along the direction of travel. In another embodiment, the platen 335 may be attached to a SCARA (Selective Compliance Articulated Robotic Arm) type robot, which translates the platen 335 along the direction of travel. This robot may be different from the vacuum robot 210 described above. In another embodiment, the scanning system may include a linear motor, wherein the platen 335 is supported by bearings that rest on rails. In another embodiment, the scanning system may be a linkage design with straight line motion. Of course, other scanning systems that produce reciprocating horizontal motion may be used.

Note that the speed of the scanning system may be constant in both directions, traveling to and from the ending position. In another embodiment, the movable platen assembly may pass through the output beam from the first plasma source 310 at a different speed than it passes through the output beam from the second plasma source 320.

A controller 400 may be in communication with the cluster tool. The controller 400 may include a processing unit, such as a microcontroller, a personal computer, a special purpose controller, or another suitable processing unit. The controller 400 may also include a non-transitory storage element, such as a semiconductor memory, a magnetic memory, or another suitable memory. This non-transitory storage element may contain instructions and other data that allows the controller 400 to perform the functions described herein. The controller 400 may be in communication with the atmospheric robot 120, the load locks 130, the vacuum robot 210, and the scanning system of the movable platen assembly 330. Additionally, the controller 400 may be in communication with the extraction voltage power supplies 312, 322, the RF power supplies 311, 321 and the workpiece bias power supply 337. In this way, the controller 400 may control the movement of workpieces through the cluster tool, as well as the parameters associated with the plasma sources as the workpieces are processed.

In operation, each processing chamber 300 may perform the same operations. For example, in one embodiment, there are two load locks 130 dedicated to each processing chamber 300. In this embodiment, the atmospheric robot 120 may move a first workpiece from a receptacle 110 to a first load lock 130. The first load lock 130 pumps down to vacuum conditions so that the first workpiece may be removed by the vacuum robot 210 using one of its arms, and placed on the movable platen assembly 330 while the movable platen assembly 330 is in the starting position, shown in FIG. 1. The movable platen assembly 330 then moves to the ending position, shown in FIG. 2. The first plasma source 310 and the second plasma source 320 may be active during this time, such that output beams from the two plasma sources are directed toward the workpiece as it moves along the direction of travel 336. As described above, the plasma sources may be configured with the same parameters or may have different parameters. The movable platen assembly 330 then moves back to the starting position, shown in FIG. 1. The first plasma source 310 and the second plasma source 320 may be active during this time, such that output beams from the two plasma sources are directed toward the workpiece as it moves along the direction of travel 336.

In some embodiments, the workpiece may travel between the starting position and the ending position a plurality of times. In other embodiments, the workpiece may travel only once to the ending position and back to the starting position.

During this time, the atmospheric robot 120 may collect another unprocessed workpiece from the receptacle 110 and place it in a second load lock 130, that is also accessible by the vacuum robot 210. The vacuum robot 210 may remove the second unprocessed workpiece from this second load lock using one of its arms. The vacuum robot 210 may hold this second unprocessed workpiece in one of its arms waiting for the first workpiece to finish processing. Once the processing of the first workpiece is finished, the vacuum robot 210 removes the processed first workpiece from the movable platen assembly 330 using the second of its arms and places the second workpiece onto the movable platen assembly 330. The vacuum robot 210 may then return the processed first workpiece to the first load lock 130 and retrieve a third unprocessed workpiece from that load lock, which may have been previously placed there by the atmospheric robot 120. When the second workpiece has completed processing, the vacuum robot 210 may remove it from the platen 335 and replace it with the third unprocessed workpiece. The second processed workpiece may then be returned to the second load lock, where a fourth unprocessed workpiece is also retrieved. Thus, in this configuration, the vacuum robot 210 returns a processed workpiece to a load lock using one of its arms, and then retrieves an unprocessed workpiece from that same load lock using its other arm. Note that if the load lock has only one slot, the removal of the unprocessed workpiece is performed prior to the return of the processed workpiece. If the load lock has two or more slots, the order of operations may be different than defined above.

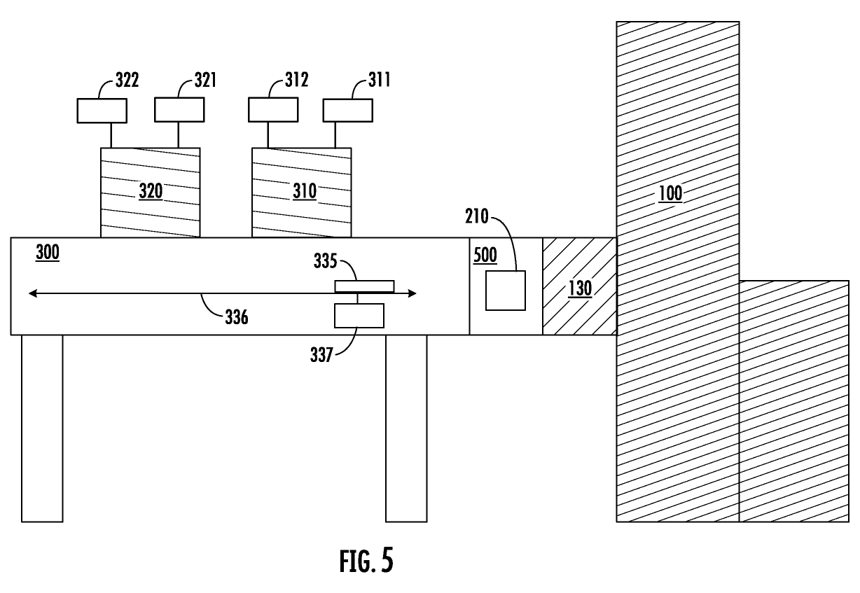

FIGS. 4-5 show a second embodiment of the cluster tool. In this embodiment, components already described in FIGS. 1-3 are given identical reference designators. FIG. 4 is a top view of this embodiment with the movable platen assembly 330 in the starting position, while FIG. 5 shows a side view of the embodiment of FIG. 4.

This embodiment introduces a buffer station 500 located between the load locks 130 and the processing chambers 300. The buffer station 500 is in communication with the processing chamber 300 and is maintained at near vacuum conditions. The buffer station 500 includes the vacuum robot 210, and may also include other components, such as an orienter 510, a cassette 520 and other components. In this way, additional operations may be performed on the workpieces while at near vacuum conditions. For example, in this embodiment, the vacuum robot 210 may remove an unprocessed workpiece from the load lock 130 and place it on the orienter 510. Once oriented, the vacuum robot 210 may remove the workpiece from the orienter 510 and place it on the platen 335 or in the cassette 520.

The cassette 520 may be used to store unoriented unprocessed workpieces, oriented unprocessed workpieces, processed workpieces or a combination thereof. The cassette 520 may be used to compensate for any mismatch in throughput between the atmospheric robot 120, the vacuum robot 210, and the processing chambers 300.

In certain embodiments, a workpiece may travel from the receptacle 110 to the load lock 130 using the atmospheric robot 120. It may then be removed from the load lock 130 by the vacuum robot 210 and placed on the orienter 510. Once aligned, the workpiece may be placed on the movable platen assembly 330. If, however, the movable platen assembly 330 is occupied, the oriented workpiece may be placed into the cassette 520. Once the processing of the workpiece that is currently on the movable platen assembly 330 is completed, another workpiece, which may be directly from the orienter 510 or from the cassette 520, may be placed on the movable platen assembly 330.

In certain embodiments, the cassette 520 may be located in the buffer station 500 at a position where it can be accessed by the vacuum robots 210 associated with two different processing chambers 300. In this way, workpieces can be transferred between vacuum robots 210 and between processing chambers 300. Further, this may also reduce the number of load locks that are used. For example, if workpieces can be moved between vacuum robots 210, in some embodiments, only two of the load locks shown in FIG. 4 may be utilized.

Additionally, the processes being performed by the first processing chamber and the second processing chamber may be the same, such that workpieces may utilize either processing chamber. In other embodiments, the processes being performed by the two processing chambers may be different. In one embodiment, workpieces may be processed by one processing chamber and then, when complete, be processed by the second processing chamber, which performs a different process, or the same type of process with different parameters.

As described above, the first plasma source 310 and the second plasma source 320 may be configured identically, or may be configured with one or more parameters that are different. Further, the plasma sources may perform the same type of process, or different types of processes.

In some embodiments, there may be a valve separating the buffer station 500 from the processing chambers 300.

The system described herein has many advantages. First, the cluster tool may include fewer components. As described above, due to the horizontal scan, air bearings, which may be problematic, may be eliminated. The removal of the air bearing and movable shaft may reduce issues associated with deposits forming on the movable shaft and entering the air bearing. Additionally, the traditional vertical scan approach utilizes a process chamber that is at a different height than the distribution hub, such that there is a central distribution robot and also dedicated robots within each processing chamber 300. However, in the presently disclosed system, there is a single vacuum robot that interfaces with the load locks and the processing chamber 300. Because of these improvements, the overall size of the cluster tool may be smaller than is otherwise possible. For example, according to one estimate, the overall footprint of this configuration is 30% smaller than that of a conventional system that uses a central distribution hub with four process chambers. Additionally, since the workpiece is processed by two plasma sources during each pass, the throughput of this cluster tool may be improved as compared to conventional tools.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A cluster tool, comprising:
a front-end system, including an atmospheric robot;
a processing chamber configured to be pumped to near vacuum conditions, the processing chamber including a vacuum robot disposed within the processing chamber;
a first plasma source and a second plasma source coupled to the processing chamber;
a load lock disposed between the front-end system and the processing chamber; and
a movable platen assembly disposed in the processing chamber, wherein the movable platen assembly moves horizontally such that a workpiece supported by a platen in the movable platen assembly is configured to be treated by a first output beam from the first plasma source and a second output beam from the second plasma source.

2. The cluster tool of claim 1, further comprising a second load lock disposed between the front-end system and the processing chamber.

3. The cluster tool of claim 1, wherein the first plasma source and the second plasma source are identical.

4. The cluster tool of claim 1, wherein the first plasma source and the second plasma source are configured with one or more parameters that are different such that two processes are performed on each workpiece.

5. The cluster tool of claim 4, wherein the one or more parameters comprises one or more of extraction voltage, duty cycle, RF power, gas species, gas flow rate, gas ratio or gas pressure.

6. The cluster tool of claim 1, wherein one or more parameters of the movable platen assembly are changed as the platen passes through the first output beam and the second output beam.

7. The cluster tool of claim 6, wherein the one or more parameters comprises one or more of scan speed, bias voltage or duty cycle.

8. The cluster tool of claim 1, wherein the movable platen assembly moves in a reciprocating manner from a starting position near the vacuum robot to an ending position, past the second plasma source, and then returns to the starting position.

9. The cluster tool of claim 8, wherein unprocessed workpieces are placed on the movable platen assembly and processed workpieces are removed from the movable platen assembly while the movable platen assembly is in the starting position.

10. The cluster tool of claim 1, further comprising a second processing chamber, two additional plasma sources coupled to the second processing chamber, and a second vacuum robot, dedicated to the second processing chamber.

11. A cluster tool, comprising:
a front-end system, including an atmospheric robot;
a processing chamber configured to be pumped to near vacuum conditions;
a first plasma source and a second plasma source coupled to the processing chamber;
a movable platen assembly disposed in the processing chamber, wherein the movable platen assembly moves horizontally such that a workpiece supported by a platen in the movable platen assembly is configured to be treated by a first output beam from the first plasma source and a second output beam from the second plasma source;
a buffer station maintained at near vacuum conditions, in communication with the processing chamber, the buffer station including a vacuum robot disposed within the buffer station; and
a load lock disposed between the front-end system and the buffer station.

12. The cluster tool of claim 11, further comprising an orienter disposed in the buffer station.

13. The cluster tool of claim 11, further comprising a cassette disposed in the buffer station.

14. The cluster tool of claim 11, further comprising a second processing chamber, two additional plasma sources coupled to the second processing chamber, and a second vacuum robot disposed in the buffer station.

15. The cluster tool of claim 14, further comprising a cassette disposed in the buffer station at a location such that the vacuum robot and the second vacuum robot both have access to it.

16. The cluster tool of claim 11, further comprising a second load lock disposed between the front-end system and the buffer station.

17. The cluster tool of claim 11, wherein the first plasma source and the second plasma source are identical.

18. The cluster tool of claim 11, wherein the first plasma source and the second plasma source are configured with one or more parameters that are different such that two processes are performed on each workpiece.

19. The cluster tool of claim 18, wherein the one or more parameters comprises one or more of extraction voltage, duty cycle, RF power, gas species, gas flow rate, gas ratio, or gas pressure.

20. The cluster tool of claim 11, wherein one or more parameters of the movable platen assembly are changed as the platen passes through the first output beam and the second output beam.
